(19) United States
(12) Patent Application Publication
(10) Pub. No.: US 2007/0260797 A1
(43) Pub. Date: Nov. 8, 2007

(54) Memory card with an expansion function

(75) Inventor: Chien-Yuan Chen, Banchiau City (TW)

Correspondence Address: TROXELL LAW OFFICE PLLC, SUITE 1404, 5205 LEESBURG PIKE, FALLS CHURCH, VA, 22041, US

(73) Assignees: Chien-Yuan CHEN; Power Digital Card Co., Ltd.

(21) Appl. No.: 11/416,231

(22) Filed: May 3, 2006

(51) Int. Cl. G06F 13/00; H05K 7/10

(52) U.S. Cl. 710/301

(57) ABSTRACT

A memory card with an expansion function is composed of a body on which is provided with a fundamental transmission interface, and an expansion interface being linked with an internal circuit. An assembly part is additionally located at a position next to circuit junctions of this expansion interface, for serving as a structure to assemble the memory card with an external module, so as to accurately constitute an assembly of the expansion interface with circuit junctions of the external module, thereby allowing that an electric device applying this memory card to be able to use an original data storage function of the memory card, and to perform an add-on function of the external module. More particularly, the external module of different function can be replaced according to a requirement, which will greatly improve the function and value-added of memory card.

### BACKGROUND OF THE INVENTION

(a) Field of the Invention

The present invention relates to a memory card, and more particularly to a memory card which can provide for an insertion of an external module, such that an electric device is able to use an original storage function and to execute an add-on function of the external module.

(b) Description of the Prior Art

Almost all of the existing consumer electronics will be provided with a memory card slot for allowing a user to insert a memory card of given specification through the memory card slot, in order to extend a data storage capacity of the device or to serve as a carrier for unloading data, thereby increasing a convenience and an applicability in using. As the continuous prosperity of market in the similar consumer electronics (especially a digital camera, a camcorder, an MP3 player, a mobile phone, or other portable electric device), a function of the electric device itself should be correspondingly expanded and improved, so as to be in compliance with a requirement of consumers, thereby acquiring a fundamental competitiveness in the market.

Being primarily provided with an advantage of miniaturization and sophistication itself, the kind of portable electric device can be appreciated by a great deal of consumers. To cope with a design requirement of miniaturization and sophistication, the technology of parts to be applied is also primarily developed toward being miniaturized and made into chips, and its density is also getting higher and higher. Correspondingly, the device itself will be integrated as much as possible with structures of similar functions; for example, there is an electric device which supports a so-called SDIO (Secure Digital Input/Output) in the market, wherein the configured SD (Smart Digital) memory card expansion slot can provide for an insertion of the SD memory card and can support an input/output equipment of the SD interface (such as a Bluetooth card, a Wi-Fi (Wireless Fidelity) card, a GPS (Global Positioning System) receiver, a digital camera card, an FM (Frequency Modulation) broadcasting card, a fingerprint recognizer, etc.); that is, all kinds of specific functions can be added as long as an SDIO expansion card is inserted into the electric device which supports the SDIO, such as that a notebook computer with a wireless network card and a PDA (Personal Digital Assistant) with a GPS receiver is exactly a practical solution which is extremely appreciated by a user.

However, the SDIO expansion card is connected with the electric device primarily through the SD memory card expansion slot. Therefore, the electric device which is only provided with a single SD memory card expansion slot can merely be selectively used with the SDIO expansion card or the SD memory card. Although by constructing a memory in an interior of the SDIO expansion card, the electric device can be also provided with an expansion function for storing data, the entire SDIO expansion card should be replaced to execute other expansion function, due to that the SDIO expansion card belongs to an expansion card with a specific function. In other words, the data which were saved while using the Bluetooth function cannot be used in the GPS function and it will be inconvenient to repeatedly carry memory cards and expansion cards.

### SUMMARY OF THE INVENTION

Accordingly, the primary object of present invention is to provide a memory card with an expansion function, wherein a body of the memory card is provided with a fundamental transmission interface and an expansion interface which is linked with an internal circuit. An assembly part is located at a position next to circuit junctions of this expansion interface to serve as a structure for assembling the memory card with an external module, which accurately constitute the assembly of expansion interface with circuit junctions of the external module, such that the electric device applying this memory card can use an original function of data storage of the memory card, and can also execute an add-on function of the external module. More particularly, the external module of a different function can be replaced according to a requirement, which will greatly improve the function and value-added of the memory card.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a perspective view of an appearance of the present invention.

FIG. 2 shows a block diagram of fundamental structures of the present invention.

FIG. 3 shows an exploded view of FIG. 1 of the present invention.

FIG. 4 shows an exploded view of assembling a memory card with an external module of another embodiment of the present invention.

FIG. 5 shows a schematic view of a first assembly method of the present invention.

FIG. 6 shows a schematic view of a second assembly method of the present invention.

FIG. 7 shows a schematic view of a third assembly method of the present invention.

### DETAILED DESCRIPTION OF THE PREFERRED EMBODIMENTS

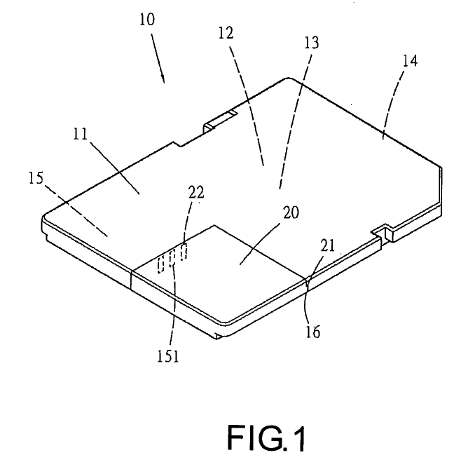

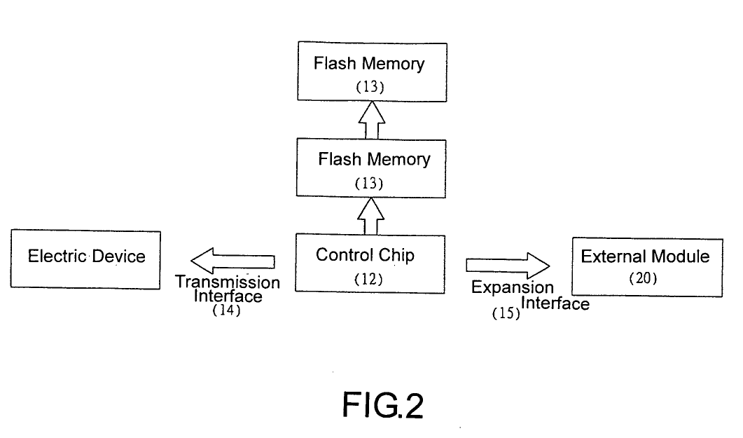

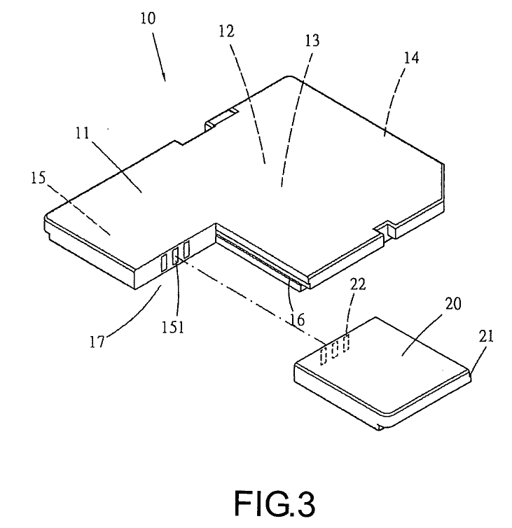

Referring to FIGS. 1 to 3, a fundamental structure of entire memory card with an expansion function of the present invention includes a body 11 on which is provided with a control chip 12, a flash memory 13, and a transmission interface 14, wherein the control chip 12 is constituted by a microcontroller unit (MCU), a random access memory (RAM), and a read-only memory (ROM), to be primarily used for performing related circuit operations, and a circuit linking is constructed by the transmission interface 14 and an electric device to be applied.

The body 11 is also provided with an expansion interface which is linked with an internal circuit of a memory card 10, and an assembly part 16 is additionally located at a position next to circuit junctions 151 of the expansion interface 15 to serve as a structure for assembling the memory card 10 with an external module 20, in order to accurately form an assembly of the expansion interface 15 with circuit junctions of the external module 20, such that the electric device which applies the memory card 10 can use an original data storage function of the memory card 10, and can perform an add-on function of the external module 20. More particularly, the external module 20 of different function can be replaced according to a requirement, which will greatly improve the function and value-added of the memory card 10.

In a physical embodiment, the expansion interface 15 is located on the body 11 of memory card 10, at a position corresponding to the other end of transmission interface 14. An indented part 17 is located at a configured position of expansion interface 15 on the body 11, the circuit junctions 151 of expansion interface 15 and the assembly part 16 of memory card 10 are located at sides of the indented part 17, respectively, and are formed into the assembly of external module 20 with the body 11 of memory card 10 with a linear groove. Naturally, they can also be assembled by latching from a top to a bottom in a saw-tooth shape (not shown in the drawings).

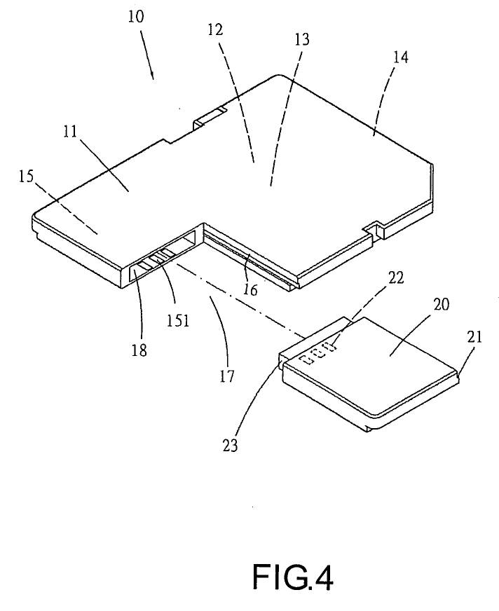

Referring to FIG. 4, a concaved base 18 can be installed at the positions of circuit junctions 151 of expansion interface 15 on the body 11 of memory card 10, and a projected lump 23 is installed on the external module 20, at a location corresponding to that of concaved base 18 of body 11, such that when the external module 20 is slid and positioned into the indented part 17 of body 11 of memory card 10 through the assembly parts 16, 21, the projected lump 23 of external module 20 can be cooperatively inserted into the concaved base 18 of body 11 of memory card 10, to increase a strength to assemble the external module 20 with the body 11 of memory card 10.

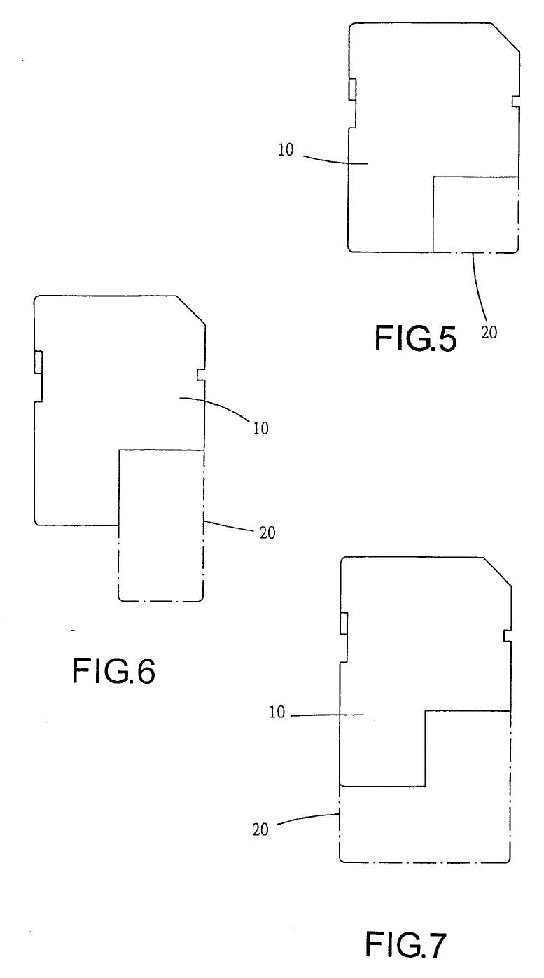

On the other hand, the external module 20 is correspondingly installed with the assembly part 21 to be assembled with the body 11 of memory card 10, and circuit junctions 22 to be linked with the expansion interface 15 of memory card 10. The external module 20 itself can be a chip module having a function of Bluetooth, Wi-Fi network card, GPS, memory card, FM broadcasting card, radio frequency identification device (RFID), fingerprint recognizer respectively, and its appearance can be shown in FIG. 1 and FIGS. 5 to 7, as long as that it will not affect an insertion and a pulling of the memory card 10. Accordingly, the present invention is able to allow the electric device to use a data storage function of the memory card 10, and to perform an add-on function of the external module. In particular, the data accessed from using the external module can be saved into a memory in an interior of the memory card 10, so as to be used by the electric device or external module of different function.

It is naturally that the assembly part 16 on the body 11 and the assembly part 20 on the external module 20 can be also provided with the function to assemble the circuit junctions in design.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A memory card with an expansion function comprising a body which is provided with a fundamental transmission interface, and an expansion interface being linked with an internal circuit, wherein an assembly part is located at a position next to circuit junctions of the expansion interface of body, to serve as a structure for assembling with an external module.

2. The memory card with an expansion function according to claim 1, wherein the expansion interface is installed on the body, at a position corresponding to the other end of transmission interface.

3. The memory card with an expansion function according to claim 1, wherein an indented part is located at a configured position of expansion interface on the body, and the circuit junctions of expansion interface and body are configured with the assembly part for assembling the body with the external module.

4. The memory card with an expansion function according to claim 2, wherein an indented part is located at a configured position of expansion interface on the body, and the circuit junctions of expansion interface and body are configured with the assembly part for assembling the body with the external module.

5. The memory card with an expansion function according to claim 1, wherein the assembly part is formed into the assembly of external module with the body of memory card with a linear groove.

6. The memory card with an expansion function according to claim 3, wherein the assembly part is formed into the assembly of external module with the body of memory card with a linear groove.

7. The memory card with an expansion function according to claim 4, wherein the assembly part is formed into the assembly of external module with the body of memory card with a linear groove.

8. The memory card with an expansion function according to claim 1, wherein the assembly part is formed into the assembly of external module with the body of memory card by latching them from a top to a bottom in a saw-tooth shape.

9. The memory card with an expansion function according to claim 3, wherein the assembly part is formed into the assembly of external module with the body of memory card by latching them from a top to a bottom in a saw-tooth shape.

10. The memory card with an expansion function according to claim 4, wherein the assembly part is formed into the assembly of external module with the body of memory card by latching them from a top to a bottom in a saw-tooth shape.

11. An external module, a body of which is provided with an assembly part for assembling with the body of memory card, and circuit junctions for linking with the expansion interface of memory card.

12. The external module according to claim 11, which can be any one or any combination of more than one of chip modules including a Bluetooth chip module, a Wi-Fi chip module, a GPS chip module, a memory card chip module, an FM broadcasting chip module, a radio frequency identification device chip module, and a fingerprint recognizing chip module.
